(19) United States
(12) Patent Application Publication
(10) Pub. No.: US 2026/0162939 A1
(43) Pub. Date: Jun. 11, 2026

(54) SUBSTRATE PROCESSING APPARATUS

(71) Applicant: Samsung Electronics Co., Ltd., Suwon-si (KR)

(72) Inventors: Jinwook Hong, Suwon-si (KR); Junyun Kweon, Suwon-si (KR); Wooju Kim, Suwon-si (KR); JUNHO YOON, Suwon-si (KR); Dayoung Cho, Suwon-si (KR); Minhaeng Heo, Suwon-si (KR)

(21) Appl. No.: 19/293,300

(22) Filed: Aug. 7, 2025

(30) Foreign Application Priority Data
Dec. 9, 2024 (KR) 10-2024-0181968

(51) Int. Cl. H01J 37/32

(52) U.S. Cl. CPC H01J 37/32174; H01J 37/32091; H01J 37/32541; H01J 37/32568; H01J 2237/334

(57) ABSTRACT

An embodiment provides a substrate processing apparatus including a chamber, a plasma excitation electrode configured to allow energy to be applied for excitation of plasma, a support positioned inside the chamber to support a substrate, at least one plasma control electrode positioned to face a space positioned above the support, and at least one control power supply connected to the plasma control electrode to supply a power for controlling a state of the plasma.

### CROSS-REFERENCE TO RELATED APPLICATION

This application claims priority to and the benefit of Korean Patent Application No. 10-2024-0181968 filed at the Korean Intellectual Property Office on Dec. 9, 2024, the entire contents of which are incorporated herein by reference.

### BACKGROUND

### (a) Field

The present disclosure relates to a substrate processing apparatus.

### (b) Description of the Related Art

To manufacture semiconductor devices, various processes such as photolithography, etching, ashing, ion implantation, thin film deposition, and cleaning are performed on a substrate so as to form a desired pattern on the substrate through a Fab process. Among these processes, the etching process is a process of removing a selected heating region in films formed on the substrate, and dry etching and wet etching are used. Thereafter, the die included in the substrate becomes an electronic component through a packaging process. An etching device using plasma is used for dry etching. In addition, dry etching may also be used to thin the wafer after the Fab process and before the packaging process.

Generally, in order to form plasma, an electromagnetic field is generated in an internal space of a chamber, and the electromagnetic field excites a process gas provided in the chamber into a plasma state.

Plasma refers to an ionized gas state including ions, electrons, radicals, etc. Plasma is generated by very high temperatures, strong electric fields, or RF electromagnetic fields. A semiconductor device manufacturing process performs an etching process using plasma. The etching process is performed by ion particles contained in the plasma colliding with the substrate.

### SUMMARY

Embodiments attempt to provide a substrate processing apparatus capable of performing substrate processing while controlling a state of plasma.

However, the problem to be solved by the embodiments of the present disclosure is not limited to the above-described problems, and can be variously extended within the scope of the technical spirit included in the present disclosure.

An aspect of the present disclosure provides a substrate processing apparatus including a chamber, a plasma excitation electrode configured to allow energy to be applied for excitation of plasma, a support disposed inside the chamber to support a substrate, at least one plasma control electrode disposed to face a space positioned above the support, and at least one control power supply connected to the plasma control electrode to supply a power for controlling a state of the plasma.

Another aspect of the present disclosure provides a substrate treating apparatus including: a chamber, a plasma excitation electrode configured to allow energy to be applied for excitation of plasma, a support disposed inside the chamber to support a substrate, a source power supply configured to supply a power for plasma excitation in a form of pulsing a power level, at least one plasma control electrode disposed to face a space positioned above the support, and at least one control power supply connected to the plasma control electrode to apply a voltage for controlling a state of the plasma.

Another aspect of the present disclosure provides a substrate treating apparatus including: a chamber, a plasma excitation electrode configured to allow energy to be applied for excitation of plasma, a support disposed inside the chamber to support a substrate, a source power supply configured to supply a power for plasma excitation in a form of pulsing a power level, a bias power supply electrically connected to the support to supply a power for bias, at least one plasma control electrode disposed to face a space positioned above the support, and at least one control power supply connected to the plasma control electrode to apply a voltage for controlling a state of the plasma.

According to the embodiments, it may be possible to provide a substrate processing apparatus capable of performing substrate processing while controlling a state of plasma.

### BRIEF DESCRIPTION OF THE DRAWINGS

FIG. 1 illustrates a substrate processing apparatus according to an embodiment.

FIG. 2 illustrates a side view showing a position relationship of a support and a plasma control electrode of FIG. 1.

FIG. 3 illustrates a top plan view showing the position relationship of the support and the plasma control electrode of FIG. 1.

FIG. 4 illustrates a view for describing a process in which a substrate is processed using a substrate processing apparatus.

FIG. 5 illustrates a level of power supplied by a source power supply according to an embodiment.

FIG. 6 illustrates a level of power supplied by a source power supply according to another embodiment.

FIG. 7 illustrates a level of voltage supplied by a bias power supply according to an embodiment.

FIG. 8 illustrates a level of voltage supplied by a bias power supply according to another embodiment.

FIG. 9 illustrates a level of voltage supplied by a bias power supply according to another embodiment.

FIG. 10 illustrates a level of voltage supplied by at least one control power supply according to an embodiment.

FIG. 11 illustrates a level of voltage supplied by at least one control power supply according to another embodiment.

FIG. 12 illustrates a level of voltage supplied by at least one control power supply according to another embodiment.

FIG. 13 illustrates a voltage applied to two plasma control electrodes disposed facing each other according to an embodiment.

FIG. 14 illustrates an electric field generated between two plasma control electrodes disposed facing each other according to FIG. 13.

FIG. 15 illustrates a voltage applied to two plasma control electrodes disposed facing each other according to another embodiment.

FIG. 16 illustrates an electric field generated between two plasma control electrodes disposed facing each other according to FIG. 15.

FIG. 17 illustrates a substrate processing apparatus according to another embodiment.

FIG. 18 illustrates a substrate processing according to another embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures. Also, these spatially relative terms such as “above” and “below” as used herein have their ordinary broad meanings—for example element A can be above element B even if when looking down on the two elements there is no overlap between them (just as something in the sky is generally above something on the ground, even if it is not directly above).

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

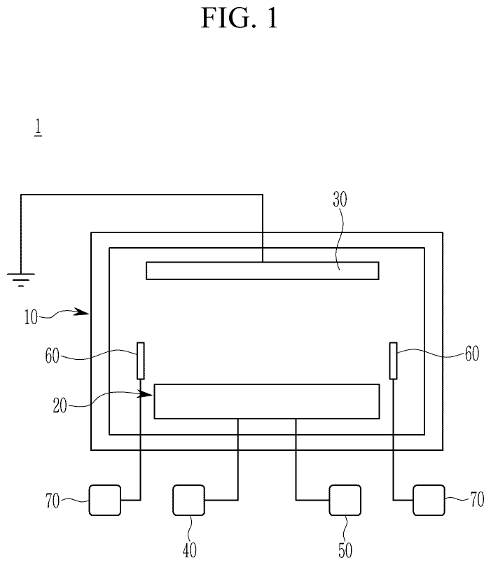

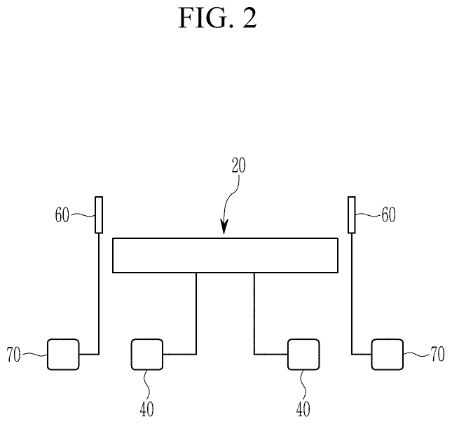

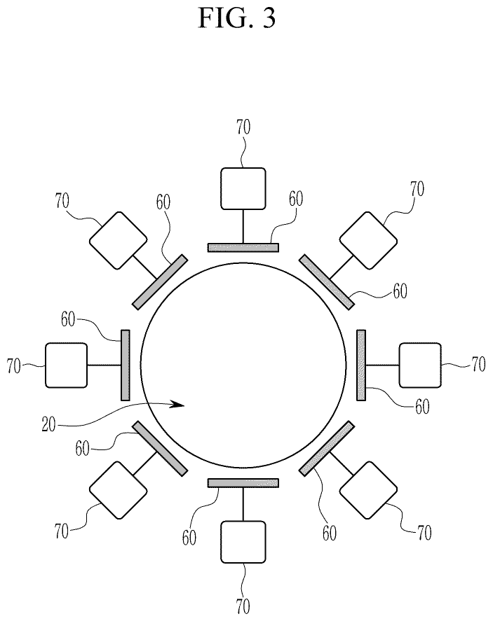

FIG. 1 illustrates a substrate processing apparatus 1 according to an embodiment, FIG. 2 illustrates a side view showing a position relationship of a support 20 and a plasma control electrode 60 of FIG. 1, and FIG. 3 illustrates a top plan view showing the position relationship of the support 20 and the plasma control electrode 60 of FIG. 1.

Referring to FIGS. 1 to 3, the substrate processing apparatus 1 according to an embodiment may include a chamber 10, the support 20, a plasma excitation electrode 30, a source power supply 40, a bias power supply 50, the plasma control electrode 60, and a control power supply 70.

The substrate processing apparatus 1 may process a substrate using plasma. For example, the substrate processing apparatus 1 may perform an etching process using excited plasma.

The chamber 10 provides a process space within which a substrate processing process is performed. The chamber 10 has an internal process space PS and may be sealed. The chamber 10 may include a housing made of a metallic material. For example, the housing of the chamber 10 may be made of an aluminum material or the like. The housing of the chamber 10 may be electrically grounded.

The support 20 may be disposed inside the chamber 10. The support 20 may be disposed at a lower portion of the process space. The support 20 supports the substrate. The support 20 may adsorb the substrate using an electrostatic force. The support 20 may include a plurality of components. The support 20 may include an electrostatic chuck and a focus ring. The electrostatic chuck may be disposed on an upper portion of the support 20. Accordingly, the substrate may be positioned on an upper surface of the electrostatic chuck. The upper surface of the electrostatic chuck may be made of a dielectric material. The focus ring may be disposed in an upper outer region of the support 20. The focus ring may be disposed on outer circumference of an upper portion of the electrostatic chuck.

A refrigerant passage may be formed inside the support 20. The refrigerant passage may provide a passage for a refrigerant to flow within the support 20. For example, the refrigerant passage may be formed in a spiral shape. In addition, the refrigerant passage may include ring-shaped passages with different radii sharing a same center. In this case, the refrigerant passage may be configured such that ring-shaped passages communicate with each other. The refrigerant may circulate through the refrigerant passage and cool the support 20. As the support 20 is cooled, the substrate positioned on the support 20 may be cooled.

The support 20 may include a portion that is formed of an electrically conductive material. The support 20 may include a portion that is formed of a metallic material. Accordingly, the support 20 may function as an electrode, and the support 20 may transmit electric current.

In the support 20, a region provided as a conductive material may be disposed below a region provided as a dielectric. For example, the region provided as a conductive material to the support 20 may be disposed in an inner region of the support 20, with the region provided as the dielectric positioned above the conductive material. Accordingly, the region provided as a conductive material in the support 20 may be limited from being exposed to plasma during the process disclosed herein.

The plasma excitation electrode 30 applies energy for excitation of plasma in the process space. A lower surface of the plasma excitation electrode 30 may be disposed inside the chamber 10. For example, the plasma excitation electrode 30 may be disposed inside the chamber 10. The plasma excitation electrode 30 may be manufactured separately from the chamber 10, such that the plasma excitation electrode 30 may be separately connected to the chamber 10. Alternatively, the plasma excitation electrode 30 may be provided integrally with an upper structure of the chamber 10, for example, by being formed with the chamber 10. That is, the upper structure of the chamber 10 may function as the plasma excitation electrode 30.

The plasma excitation electrode 30 may be disposed at an upper portion of the process space. The plasma excitation electrode 30 may be made of a conductive material, and may have a shape with a predetermined area. The lower surface of the plasma excitation electrode 30 may be disposed to face the support 20 in a vertical direction, for example, with the lower surface of the plasma control electrode spaced a distance apart from an upper surface of the support 20.

The source power supply 40 may provide a power for plasma excitation. The source power supply 40 may be electrically connected to the support 20. The source power supply 40 may be electrically connected to a region provided with a conductive material in the support 20. The source supply device 40 may include a high-frequency power supply that generates a high-frequency power. The source power supply 40 may include an RF power supply and may supply power having a frequency within a range from 2 MHz to 500 MHz, or from 50 MHz to 200 MHz.

The bias power supply 50 may be electrically connected to the support 20 to supply a power for bias. The bias power supply 50 may be electrically connected to a region provided with a conductive material in the support 20. In some embodiments, the bias power supply 50 may apply a voltage or current to the conductive material in the support 20, and may comprise a DC voltage, a low-frequency AC voltage, or a pulsing voltage. A sheath state, a concentration state of plasma on the substrate, a state of incidence or direction of ions on the substrate, etc. may be adjusted in a region adjacent to the upper surface of the support 20 by the power supplied by the bias power supply 50. The bias power supply 50 may be provided to include a voltage source to output a voltage.

A process gas introduced into the chamber 10 may be excited into plasma by an electric field formed inside the chamber 10. Specifically, the process gas can be excited into plasma by a capacitively coupled plasma (CCP) source. The capacitively coupled plasma source may include an upper electrode (e.g., the plasma excitation electrode 30) and a lower electrode (e.g., the support 20). The upper electrode and the lower electrode may be disposed to face each other in the vertical direction inside the chamber 10. An electromagnetic field is formed in the space between the upper electrode and the lower electrode by applying high frequency power to at least one of the upper electrode or the lower electrode, and the process gas supplied to this space may be excited into a plasma state. The upper electrode may serve as the plasma excitation electrode 30, and the lower electrode may serve as the support 20. The high-frequency power supply may be connected to one of the upper and lower electrodes (e.g., plasma excitation electrode 30 or support 20). For example, the upper electrode may be grounded, and the lower electrode may be connected to the high-frequency power supply. Alternatively, the lower electrode may be grounded, and the upper electrode may be connected to the high-frequency power supply. Additionally, the high-frequency power supply may be connected to both the upper and lower electrodes. FIG. 1 illustrates an example where a high-frequency power source is connected to the lower electrode.

The plasma control electrode 60 may control a state of plasma in a space positioned above the support 20. The plasma control electrode 60 may control distribution of plasma ions positioned above the support 20. The plasma control electrode 60 may have a plate structure having a preset area. The plasma control electrode 60 may include at least a portion that is formed of a conductive material.

The plasma control electrode 60 may be disposed outside the space positioned above the support 20. When viewed from above (e.g., illustrated in the plan view of FIG. 3), the plasma control electrode 60 may be disposed on an outer periphery of the support 20. Accordingly, when viewed from above in a plan view, the plasma control electrode 60 may not overlap the support 20. Rather, the plasma control electrode 60 may lie outside of the outer periphery, or footprint, of the support 20 and, in some embodiments, the plasma control electrode 60 may lie outside of the outer periphery, or footprint, of the plasma excitation electrode 30. The plasma control electrode 60 may be mounted within the chamber 10, for example, by being attached to one or more of the walls of the chamber 10. In some embodiments, the plasma control electrode 60 may be separate from the support 20 and the plasma excitation electrode 30, for example, with the plasma control electrode 60 not in contact with the support 20 and the plasma excitation electrode 30 such that a gap or a space may exist between the plasma control electrode 60 and both the support 20 and the plasma excitation electrode 30.

When viewed from above, the plasma control electrode 60 may have a first surface facing the support 20, wherein the first surface is the portion of the plasma control electrode 60 that is closest to the space above the support 20. That is, a first surface of the plasma control electrode 60 may face the space positioned above the support 20. By having the plate structure, the plasma control electrode 60 may comprise the first surface (e.g., illustrated in FIG. 3), which may be a flat or planar first surface that faces the space positioned above the support 20. The plate structure of the plasma control electrode 60 may comprise a quadrilateral shape (e.g., square, rectangular, etc.), for example, with the first surface having the quadrilateral shape, though, the plate structure may comprise other shapes, such as, for example, a circular shape, an oval shape, etc. In some embodiments, by facing the space above the support 20, a line or axis that is perpendicular to the first surface of the plasma control electrode 60 may pass through the space above the support 20, for example, with the line or axis passing between the support 20 and the plasma excitation electrode 30.

When viewed from above, a first surface of the plasma control electrode 60 may face a central region of the support 20. The central region of the support 20 may comprise the region that is near, or encompasses, a center or midpoint of the support 20 relative to a horizontal direction. The first surface of the plasma control electrode 60 may face a space positioned above the central region of the support 20. In some embodiments, by facing the space above the central region of the support 20, a line or axis that is perpendicular to the first surface of the plasma control electrode 60 may pass through the space above the central region.

The plasma control electrode 60 may have at least a portion positioned above an upper surface of the support 20. Accordingly, at least a portion of a first surface of the plasma control electrode 60 may face a space positioned above the support 20 in a horizontal direction. For example, a lower end of the plasma control electrode 60 may be disposed above the upper surface of the support 20. Accordingly, a first surface of the plasma control electrode 60 may face the space positioned above the support 20 in the horizontal direction. In some embodiments, the plasma control electrode 60 may be oriented such that the first surface lies in a plane that is perpendicular to a plane within which the upper surface of the support 20 lies. As such, a line or axis that is perpendicular to the first surface of the plasma control electrode 60 may be parallel to the upper surface of the support 20 and/or may be parallel to a lower surface of the plasma excitation electrode 30. Alternatively, in some embodiments, the plasma control electrode 60 may be oriented such that the first surface lies in a plane that is not perpendicular to a plane within which the upper surface of the support 20 lies. For example, the first surface of the plasma control electrode 60 may be oriented such that a line or axis that is perpendicular to the first surface of the plasma control electrode 60 may not be parallel to the upper surface of the support 20.

A plurality of plasma control electrodes 60 may be provided, and the plasma control electrodes 60 may be disposed on an outer periphery of the space positioned above the support 20 while being spaced apart from each other. Accordingly, the plasma control electrodes 60 may face each other with the space positioned above the support 20 therebetween. For example, as illustrated in FIG. 3, two plasma control electrodes 60 may be provided facing each other with a space positioned above the center of the support 20 therebetween. The two plasma control electrodes 60 may be arranged to face each other such that a line or axis that is perpendicular to the first surface of one of the plasma control electrode 60 may be parallel to, and co-linear with, a line or axis that is perpendicular to the first surface of an opposing plasma control electrode 60. As illustrated in FIG. 3, the support 20 may comprise a circular shape, and two plasma control electrodes 60 that are arranged to face each other may be 180 degrees apart about the support 20.

FIG. 3 illustrates an example in which eight plasma control electrodes 60 are provided, but this is merely an example, and a number of plasma control electrodes 60 may be more or less than this.

The control power supply 70 may be electrically connected to the plasma control electrode 60 to provide a power for controlling the state of plasma. The control power supply 70 may be electrically connected to a region that is provided with a conductive material in the plasma control electrode 60. The control power supply 70 may be provided to include a voltage source to output a voltage. The state of the plasma positioned in the space above the support 20 may be controlled by a power supplied by the control power supply 70. A plurality of control power supplies 70 may be provided. For example, a number of control power supplies 70 may be equal to that of plasma control electrodes 60. Then, the control power supplies 70 may be connected one-to-one to the plasma control electrodes 60, respectively. For example, one control power supply 70 (e.g., a first control power supply 70) may be electrically connected to one plasma control electrode 60 (e.g., a first plasma control electrode 60), another control power supply 70 (e.g., a second control power supply 70) may be electrically connected to another plasma control electrode 60 (e.g., a second plasma control electrode 60), etc. Accordingly, the voltage applied to the plasma control electrodes 60 may be individually controlled. For example, the first control power supply 70 may apply a first voltage to the first plasma control electrode 60, while the second control power supply 70 may apply a second voltage to the second plasma control electrode 60, wherein the first voltage may be the same as, or different than, the second voltage. The other control power supplies 70 and plasma control electrodes 60 may be controlled in a similar manner. In addition, the number of the control power supplies 70 may be smaller than that of the plasma control electrodes 60, for example, with one control power supply electrically connected to more than one plasma control electrode 60. As such, at least one of the control power supplies 70 may be connected to two or more plasma control electrodes 60.

FIG. 3 illustrates an example in which the number of control power supplies 70 equals the number of plasma control electrodes 60, and each control power supply 70 is connected to one plasma control electrode 60.

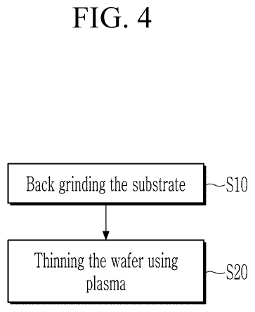

FIG. 4 illustrates a process in which a substrate is processed using the substrate processing apparatus 1.

Referring to FIG. 4, the substrate processing apparatus 1 may perform a thinning process using plasma (S20). That is, the substrate processing apparatus 1 may thin a wafer by performing etching on a surface of the substrate on which the wafer is positioned.

The substrate processed by the substrate processing apparatus 1 may have a circuit pattern positioned on the wafer through a FAB process. Then, through a packaging process, each die included in the substrate may become a separate electronic component. In this case, the substrate may be thinned through a thinning process before the packaging process. That is, the substrate may be positioned on the support 20 such that a circuit pattern faces downward (e.g., toward the support 20) and the wafer faces upward (e.g., toward the plasma excitation electrode 30), and then etched using plasma so that a thickness of the wafer may be reduced.

The substrate may undergo back-grinding (S10) before being processed by the substrate processing apparatus 1. That is, a substrate on which a circuit pattern is formed through a FAB process may undergo a grinding process on the wafer. The grinding process may be performed by bringing a substrate polishing member, such as a polishing pad, into contact with the wafer and then rotating either the substrate polishing member or the wafer. Accordingly, a thickness of the wafer may be reduced. Thereafter, the substrate may be further processed through the substrate processing apparatus 1, so that the thickness of the wafer may be further reduced. That is, as the substrate is thinned through plasma, it may become so thin that it cannot be processed through back grinding due to concerns about breakage.

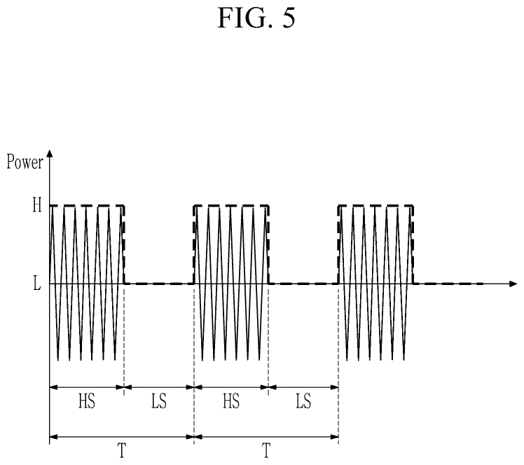

FIG. 5 illustrates a level of power supplied by the source power supply 40 according to an embodiment. A horizontal axis represents time, and a vertical axis represents power.

Referring to FIG. 5, a level of power supplied by the source power supply 40 may be pulsed over time. An output of the source power supply 40 may include a high-level section HS and a low-level section LS. A low power level L of the low-level section LS may be less than a high-power level H of the high-level section HS. The high-level section HS may be a source power-on section, and the low-level section LS may be a source power-off section. Accordingly, the low power level L of the low-level section LS may be 0 W.

One high-level section HS and one low-level section LS may together constitute one cycle T of an output of the source power supply 40. That is, the output of the source power supply 40 may repeat for one cycle T with a preset length. In addition, one cycle T may include the high-level section HS and the low-level section LS.

An output signal of the source power supply 40 may have a preset RF frequency. For example, the RF frequency of the output signal from the source power supply 40 may range from 50 MHz to several hundred MHz. A waveform of the output signal of the source power supply 40 may be a sine wave, etc. In addition, a power level of an output of the source power supply 40 may be an envelope of an output signal with an RF frequency, wherein the envelope may represent pulsing of the RF power. For example, the output signal of the source power supply 40 may have an amplitude that changes over time. In this case, a change in amplitude may include an amplitude that becomes zero. Accordingly, the power level of the output of the source power supply 40 may be pulsed.

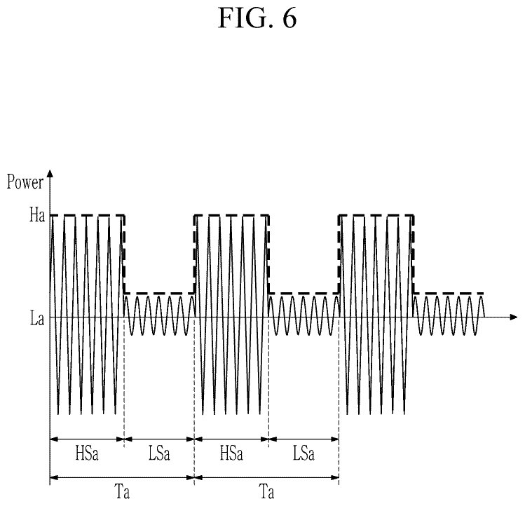

FIG. 6 illustrates a level of power supplied by the source power supply 40 according to another embodiment. A horizontal axis represents time, and a vertical axis represents power.

Referring to FIG. 6, a level of power supplied by the source power supply 40 may be pulsed over time. Specifically, an output of the source power supply 40 may include a high-level section HSa and a low-level section LSa. The high-level section HSa and the low-level section LSa may be source power-on sections. A low power level of the low-level section LSa may be less than a high-power level Ha of the high-level section HSa. The low power level of the low-level section LSa may exceed 0 W.

One high-level section HSa and one low-level section LSa may together constitute one cycle Ta of an output of the source power supply 40. That is, the output of the source power supply 40 may repeat for one cycle Ta with a preset length. In addition, one cycle Ta may include the high-level section HSa and the low-level section LSa.

An output signal of the source power supply 40 may have a preset RF frequency. For example, the RF frequency of the output signal from the source power supply 40 may range from 50 MHz to several hundred MHz. A waveform of the output signal of the source power supply 40 may be a sine wave, etc. In addition, a power level of an output of the source power supply 40 may be an envelope of an output signal with an RF frequency, wherein the envelope may represent pulsing of the RF power. For example, the output signal of the source power supply 40 may have an amplitude that changes over time. Accordingly, the power level of the output of the source power supply 40 may be pulsed.

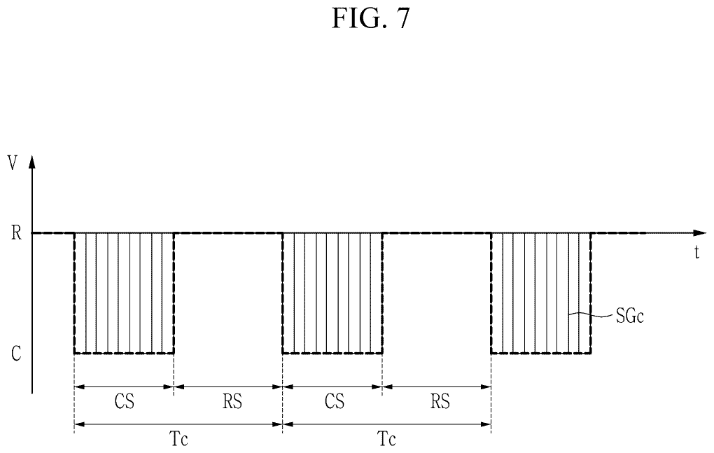

FIG. 7 illustrates a level of voltage supplied by the bias power supply 50 according to an embodiment. A horizontal axis represents time, and a vertical axis represents voltage.

Referring to FIG. 7, a level of voltage supplied by the bias power supply 50 may be pulsed over time. Specifically, an output of the bias power supply 50 may include a bias section CS and a reference section RS. The bias power supply 50 may output a bias voltage level C in the bias section CS. The bias voltage level C may be provided as a negative voltage value.

A length of one cycle Tc of the output of the bias power supply 50 may correspond to the length of one cycle (e.g., T in FIG. 5 or Ta in FIG. 6) of the output of the source power supply 40. For example, the length of one cycle Tc of the output of the bias power supply 50 may be equal to the length of one cycle (e.g., T in FIG. 5 or Ta in FIG. 6) of the output of the source power supply 40.

One cycle Tc of the output of the bias power supply 50 may include the bias section CS and a reference section RS, for example, with one cycle Tc being equal to one bias section CS and one reference section RS. Any section other than the bias section CS during one cycle Tc may be the reference section RS. That is, the output of the bias power supply 50 may be changed between the bias section CS and the reference section RS.

The bias power supply 50 may output a reference voltage level R in the reference section RS. That is, the output of the bias power supply 50 may be the reference voltage level R in front of the bias section CS. The output of the bias power supply 50 may be the reference voltage level R following the bias section CS. The reference voltage level R may have a value that is greater than the bias voltage level C. An absolute value of the reference voltage level R may be smaller than an absolute value of the bias voltage level C. The reference voltage level R may be 0V.

An output signal SGc of the bias power supply 50 may have a preset bias frequency. For example, the bias frequency may be 300 KHz to 600 KHz. The output signal SGc of the bias power supply 50 may be a pulse of DC voltage. A waveform of the output signal SGc of the bias power supply 50 may be a square wave, etc. In addition, a power level of an output of the bias power supply 50 may be an envelope of the output signal having the bias frequency. For example, the output signal SGc of the bias power supply 50 may have an amplitude that changes over time. In this case, a change in amplitude may include an amplitude that becomes zero. Accordingly, the voltage level of the output of the bias power supply 50 may be pulsed.

A length of the bias section CS of the output of the bias power supply 50 may correspond to the length of the high-level section (e.g., HS in FIG. 5 or HSa in FIG. 6) of the output of the source power supply 40. When the output of the source power supply 40 changes from the low-level section (e.g., LS in FIG. 5 or LSa in FIG. 6) to the high-level section (e.g., HS in FIG. 5 or HSa in FIG. 6), the output of the bias power supply 50 may change from the reference section RS to the bias section CS. When the output of the source power supply 40 changes from the high-level section (e.g., HS in FIG. 5 or HSa in FIG. 6) to the low-level section (e.g., LS in FIG. 5 or LSa in FIG. 6), the output of the bias power supply 50 may change from the bias section CS to the reference section RS.

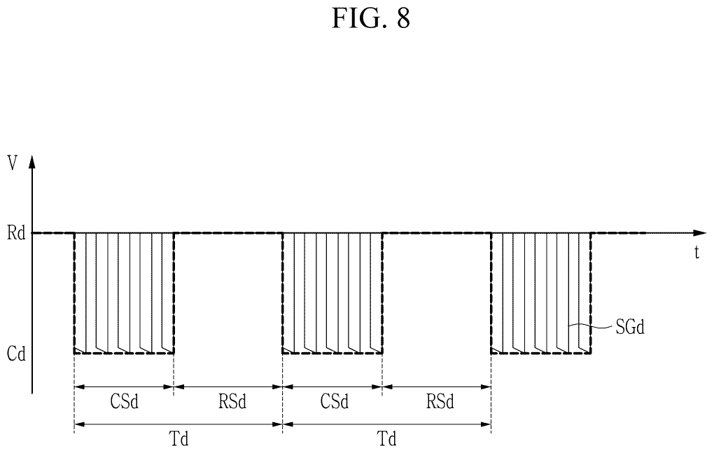

FIG. 8 illustrates a level of voltage supplied by the bias power supply 50 according to another embodiment. A horizontal axis represents time, and a vertical axis represents voltage.

Referring to FIG. 8, a level of voltage supplied by the bias power supply 50 may be pulsed over time. Specifically, an output of the bias power supply 50 may include a bias section CSd and a reference section RSd. The bias power supply 50 may output a voltage at the bias voltage level Cd in the bias section (CSd). The bias voltage level Cd may be provided as a negative voltage value.

A length of one cycle Td of the output of the bias power supply 50 may correspond to the length of one cycle (e.g., T in FIG. 5 or Ta in FIG. 6) of the output of the source power supply 40. One cycle Td of the output of the bias power supply 50 may include one bias section CSd and one reference section RSd. Any section other than the bias section CSd during one cycle Td may be the reference section RSd. That is, the output of the bias power supply 50 may be changed between the bias section CSd and the reference section RSd.

The bias power supply 50 may output a reference voltage level Rd in the reference section RSd. That is, the output of the bias power supply 50 may be the reference voltage level Rd in front of the bias section CSd. The output of the bias power supply 50 may be the reference voltage level Rd following the bias section CSd. The reference voltage level Rd may have a value that is greater than the bias voltage level Cd. An absolute value of the reference voltage level Rd may be smaller than an absolute value of the bias voltage level Cd. The reference voltage level Rd may be 0V.

An output signal SGd of the bias power supply 50 may have a preset bias frequency. For example, the bias frequency may be 300 KHz to 600 KHz. The waveform of the output signal SGd of the bias power supply 50 may be non-sinusoidal. For example, the waveform of the output signal SGd of the bias power supply 50 may have a slope in an on-duty section, for example, in the bias section CSd. Specifically, the waveform of the output signal SGd of the bias power supply 50 may have a slope that slopes downward (i.e., absolute value of the voltage increases) over time in the on-duty section. In addition, a voltage level of the output of the bias power supply 50 may be an envelope of the output signal SGd of the bias power supply 50 having a bias frequency. For example, the output signal SGd of the bias power supply 50 may have an amplitude that changes over time. In this case, a change in amplitude may include an amplitude that becomes zero. Accordingly, the voltage level of the output of the bias power supply 50 may be pulsed.

A length of the bias section CSd of the output of the bias power supply 50 may correspond to the length of the high-level section (e.g., HS in FIG. 5 or HSa in FIG. 6) of the output of the source power supply 40. When the output of the source power supply 40 changes from the low-level section (e.g., LS in FIG. 5 or LSa in FIG. 6) to the high-level section (e.g., HS in FIG. 5 or HSa in FIG. 6), the output of the bias power supply 50 may change from the reference section RSd to the bias section CSd. When the output of the source power supply 40 changes from the high-level section (e.g., HS in FIG. 5 or HSa in FIG. 6) to the low-level section (e.g., LS in FIG. 5 or LSa in FIG. 6), the output of the bias power supply 50 may change from the bias section CSd to the reference section RSd.

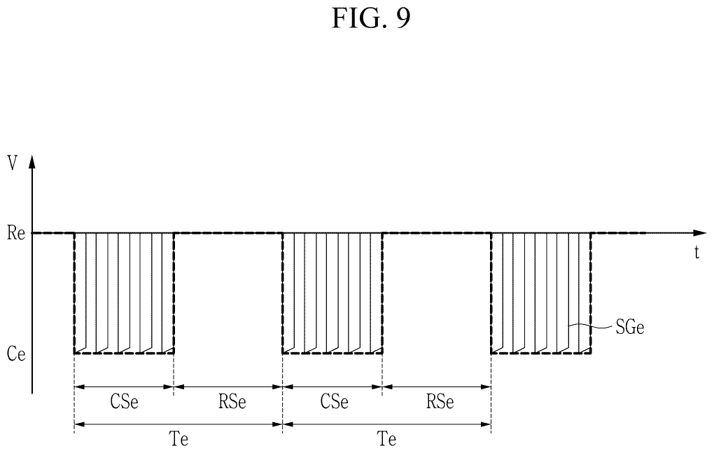

FIG. 9 illustrates a level of voltage supplied by the bias power supply 50 according to another embodiment. A horizontal axis represents time, and a vertical axis represents voltage.

Referring to FIG. 9, a level of voltage supplied by the bias power supply 50 may be pulsed over time. Specifically, an output of the bias power supply 50 may include a bias section CSe and a reference section RSe. The bias power supply 50 may output a bias voltage level Ce in the bias section CSe. The bias voltage level Ce may be provided as a negative voltage value.

A length of one cycle Te of the output of the bias power supply 50 may correspond to the length of one cycle (e.g., T in FIG. 5 or Ta in FIG. 6) of the output of the source power supply 40. One cycle Te of the output of the bias power supply 50 may include the bias section CSe and a reference section RSe. Any section other than the bias section CSe during one cycle Te may be the reference section RSe. That is, the output of the bias power supply 50 may be changed between the bias section CSe and the reference section RSe.

The bias power supply 50 may output a reference voltage level Re in the reference section RSe. That is, the output of the bias power supply 50 may be the reference voltage level Re in front of the bias section CSe. The output of the bias power supply 50 may be the reference voltage level Re following the bias section CSe. The reference voltage level Re may have a value that is greater than the bias voltage level Ce. An absolute value of the reference voltage level Re may be smaller than an absolute value of the bias voltage level Ce. The reference voltage level Re may be 0V.

An output signal SGe of the bias power supply 50 may have a preset bias frequency. For example, the bias frequency may be 300 KHz to 600 KHz. The waveform of the output signal SGe of the bias power supply 50 may be non-sinusoidal. For example, the waveform of the output signal SGe of the bias power supply 50 may have a slope in an on-duty section, for example, in the bias section CSe. Specifically, the waveform of the output signal SGd of the bias power supply 50 may have a slope that slopes upward (i.e., absolute value of the voltage decreases) over time in the on-duty section. In addition, a power level of an output of the bias power supply 50 may be an envelope of the output signal SGe having the bias frequency. For example, the output signal SGe of the bias power supply 50 may have an amplitude that changes over time. In this case, a change in amplitude may include an amplitude that becomes zero. Accordingly, the voltage level of the output of the bias power supply 50 may be pulsed.

A length of the bias section CSe of the output of the bias power supply 50 may correspond to the length of the high-level section (e.g., HS in FIG. 5 or HSa in FIG. 6) of the output of the source power supply 40. When the output of the source power supply 40 changes from the low-level section (e.g., LS in FIG. 5 or LSa in FIG. 6) to the high-level section (e.g., HS in FIG. 5 or HSa in FIG. 6), the output of the bias power supply 50 may change from the reference section RSe to the bias section CSe. When the output of the source power supply 40 changes from the high-level section (e.g., HS in FIG. 5 or HSa in FIG. 6) to the low-level section (e.g., LS in FIG. 5 or LSa in FIG. 6), the output of the bias power supply 50 may change from the bias section CSe to the reference section RSe.

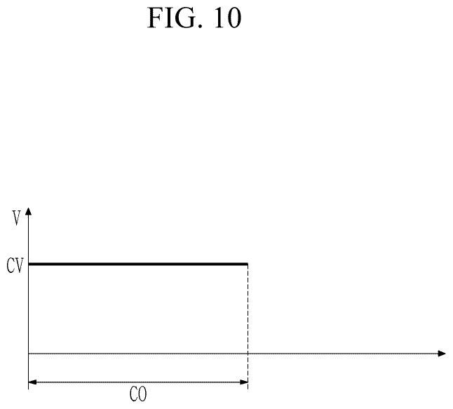

FIG. 10 illustrates a level of voltage supplied by at least one control power supply 70 according to an embodiment. A horizontal axis represents time, and a vertical axis represents voltage.

Referring to FIG. 10, the control power supply 70 may supply a voltage of a control value CV to the plasma control electrode 60. The control value CV supplied by the control power supply 70 may be sustained for a control period CO. A length of the control period CO may exceed the length of one cycle (e.g., T in FIG. 5 or Ta in FIG. 6) of the output of the source power supply 40. The length of the control period CO may exceed a length of several cycles of the output of the source power supply 40. For example, the control period CO may correspond to a length of time during which the source power supply 40 supplies power for plasma excitation. That is, while substrate processing is performed using plasma in the substrate processing apparatus 1, the control power supply 70 may continuously supply power to the plasma control electrode 60.

When a plurality of plasma control electrodes 60 are provided, a voltage of a same magnitude may be applied to the plasma control electrodes 60. For example, the plasma control electrodes 60 may be connected to one control power supply 70 that may apply the voltage of the same magnitude to each of the plasma control electrodes 60. In addition, when a plurality of control power supplies 70 are provided, each of the control power supplies 70 may be connected to at least one plasma control electrode 60. In addition, each control power supply 70 may output a voltage of the same control value CV to a respective plasma control electrode 60 to which each control power supply 70 is connected.

In some embodiments, when a plurality of plasma control electrodes 60 are provided, a voltage of a different magnitude from that of the rest may be applied to at least one of the plasma control electrodes 60. That is, when a plurality of control power supplies 70 are provided, the control value CV of at least one control power supply 70 may be different from the control values CV of one or more of the remaining control power supplies 70. In addition, when a plurality of control power supplies 70 are provided, each of the control power supplies 70 may be connected to at least one plasma control electrode 60.

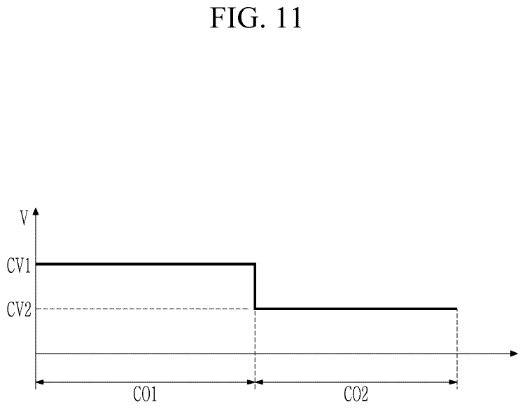

FIG. 11 illustrates a level of voltage supplied by at least one control power supply 70 according to another embodiment. A horizontal axis represents time, and a vertical axis represents voltage.

Referring to FIG. 11, a magnitude of the voltage output by the control power supply 70 may change at least once while substrate processing is performed using plasma. For example, the magnitude of the voltage output by the control power supply 70 may have a first control value CV1 during a first control period CO1, and then the magnitude of the voltage may have a second control value CV2 during a second control period CO2. A length of the first control period CO1 may exceed the length of one cycle (e.g., T in FIG. 5 or Ta in FIG. 6) of the output of the source power supply 40. The length of the first control period CO1 may exceed a length of several cycles of the output of the source power supply 40. A length of the second control period CO2 may exceed the length of one cycle (e.g., T in FIG. 5 or Ta in FIG. 6) of the output of the source power supply 40. The length of the second control period CO2 may exceed a length of several cycles of the output of the source power supply 40. FIG. 11 illustrates a case where the second control value CV2 is smaller than the first control value CV1, but, in other embodiments, the second control value CV2 may be greater than the first control value CV1.

In addition, when a plurality of control power supplies 70 are provided, one or more of the control power supplies 70 may output a voltage as illustrated in FIG. 10, while one or more of the remaining control power supplies 70 may output a voltage as illustrated in FIG. 11. Additionally, at least one of the control power supplies 70 may be turned off while substrate processing using plasma is performed.

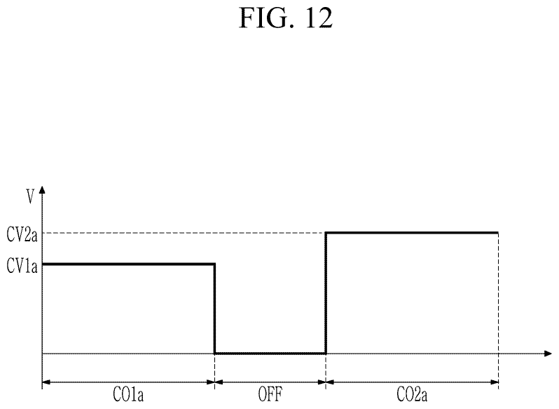

FIG. 12 illustrates a level of voltage supplied by at least one control power supply 70 according to another embodiment. A horizontal axis represents time, and a vertical axis represents voltage.

Referring to FIG. 12, the control power supply 70 may be turned off at least once while substrate processing using plasma is performed. For example, the control power supply 70 may output a first control value CV1a during a first control period CO1a and output a second control value CV2a during a second control period CO2a. Additionally, an off period OFF may be positioned between the first control period CO1a and the second control period CO2a.

A length of the first control period CO1a may exceed the length of one cycle (e.g., T in FIG. 5 or Ta in FIG. 6) of the output of the source power supply 40. The length of the first control period CO1a may exceed a length of several cycles of the output of the source power supply 40. A length of the second control period CO2a may exceed the length of one cycle (e.g., T in FIG. 5 or Ta in FIG. 6) of the output of the source power supply 40. The length of the second control period CO2a may exceed a length of several cycles of the output of the source power supply 40.

A length of the off interval OFF may exceed the length of one cycle of the output of the source power supply 40.

FIG. 12 illustrates a case where the second control value CV2a is greater than the first control value CV1a. However, in other embodiments, the second control value CV2a may be less than the first control value CV1a. In further embodiments, the second control value CV2a may be equal to the first control value CV1a.

In addition, when a plurality of control power supplies 70 are provided, one or more of the control power supplies 70 may output a voltage as illustrated in FIG. 10 or FIG. 11, while one or more of the remaining control power supplies 70 may output a voltage as illustrated in FIG. 12. Additionally, one or more of the control power supplies 70 may be turned off while substrate processing using plasma is performed.

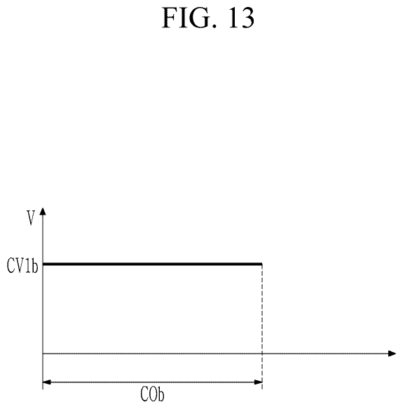

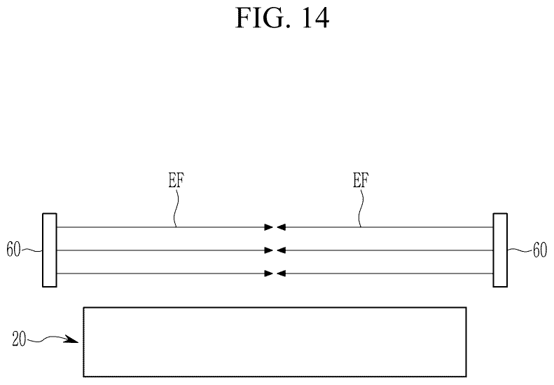

FIG. 13 illustrates a voltage applied to two plasma control electrodes 60 disposed facing each other according to an embodiment, and FIG. 14 illustrates an electric field EF generated between two plasma control electrodes disposed facing each other according to FIG. 13.

Referring to FIGS. 13 and 14, while substrate processing using plasma is performed, magnitudes of voltages applied to two plasma control electrodes 60 disposed facing each other may be the same. The two plasma control electrodes 60 are facing each other such that a line or axis that is perpendicular to the first surface of one of the plasma control electrode 60 may be co-linear with a line or axis that is perpendicular to the first surface of an opposing plasma control electrode 60, such that the plasma control electrodes 60 that face each other may be 180 degrees apart about a vertical axis that passes through the support 20, for example, with the vertical axis passing through a center of the support 20. With reference to FIG. 13, two plasma control electrodes 60 disposed facing each other may each be applied with a voltage of a control value CV1b during a control period COb. A length of the control period COb may exceed the length of one cycle (e.g., T in FIG. 5 or Ta in FIG. 6) of the output of the source power supply 40. The length of the control period COb may exceed a length of several cycles of the output of the source power supply 40. For example, the length of the control period COb may correspond to a length of time during which the source power supply 40 supplies power for plasma excitation. Additionally, the length of the control period COb may be shorter than a length of time during which the source power supply 40 supplies power for plasma excitation. The control power supply 70 that applies voltage to each of two plasma control electrodes 60 disposed facing each other may output voltage to the plasma control electrodes 60 according to one of the embodiments described above with reference to FIGS. 10 to 12.

Accordingly, the electric field EF generated from each of the two plasma control electrodes 60 disposed facing each other may be directed toward a space positioned above the support 20. For example, as illustrated in FIG. 14, when a first surface of the plasma control electrode 60 faces a space positioned above a central region of the support 20, the electric field EF generated in the plasma control electrode 60 may face a space positioned above the central region of the support 20. Strengths of the electric fields EF generated from each of the two plasma control electrodes 60 disposed facing each other may correspond to each other.

The electric field EF generated between the plasma control electrodes 60 of FIG. 14 may control a state of the plasma positioned in the upper space of the support 20. The electric field EF generated between the plasma control electrodes 60 may control a movement state of plasma ions. The ions generated when plasma is excited may have their movement state controlled by the electric field EF. Cations may be influenced in a direction of the electric field EF. Accordingly, the cations may move from a region positioned above an edge region of the support 20 toward a region positioned above the center region of the support 20 due to the electric field EF being oriented toward the center region. Additionally, anions may move in an opposite direction from the cations, for example, with the anions moving from the region positioned above the center region of the support 20 to the region positioned above an edge region of the support 20.

In addition, as described above, a level of power supplied by the source power supply 40 may be pulsed. In this case, the ions generated when the plasma is excited may change at a speed slower than a change in the level of power supplied by the source power supply 40. That is, as the level of power supplied by the source power supply unit 40 changes from the high-power level (e.g., H in FIG. 5 or Ha in FIG. 6) to the low power level (e.g., L in FIG. 5 or La in FIG. 6), a density of ions generated when plasma is excited may begin to decrease relatively gradually from a time when the low-level section (e.g., LS in FIG. 5 or LSa in FIG. 6) begins. For example, as described above in FIG. 5, even when the low power level L of the source power supply 40 is 0 W, density of ions generated when the plasma is excited at the start of the low-level section LS may not become 0. In addition, the control power supply 70 may apply a voltage to the plasma control electrode 60 even when the power level of the source power supply 40 is at a low power level (e.g., L in FIG. 5 or La in FIG. 6). Accordingly, the ions remaining in the space positioned above the support 20 during the low-level section (e.g., LS in FIG. 5 or LSa in FIG. 6) may have their movement direction controlled by the electric field EF generated between the plasma control electrodes 60. For example, when first surfaces of the plasma control electrodes 60 face a space positioned above a central region of the support 20, a state of plasma may be controlled in such a way that density of cations increases toward an upper side of the central region of the support 20 by the electric field EF generated in the plasma control electrode 60.

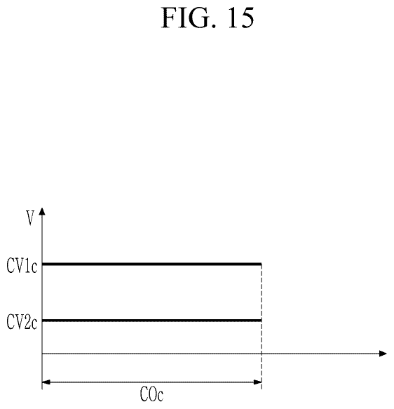

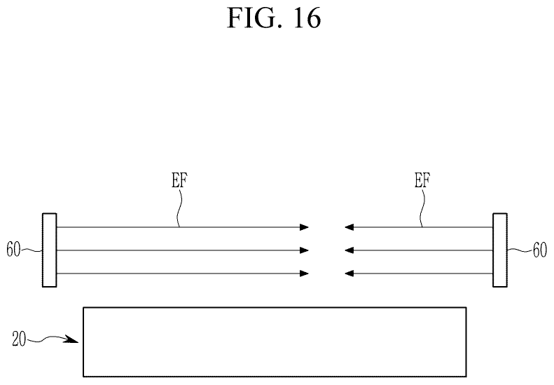

FIG. 15 illustrates a voltage applied to two plasma control electrodes 60 disposed facing each other according to another embodiment, and FIG. 16 illustrates an electric field generated between two plasma control electrodes 60 disposed facing each other according to FIG. 15.

Referring to FIGS. 15 and 16, while substrate processing using plasma is performed, magnitudes of voltages applied to two plasma control electrodes 60 disposed facing each other may be different. For example, voltages of different magnitudes may be applied to two plasma control electrodes 60 disposed facing each other during the control period COc. A first control value CV1c may be applied to a first plasma control electrode 60 of the two plasma control electrodes 60 positioned facing each other, and a second control value CV2c may be applied to a second plasma control electrode 60 of the two plasma control electrodes 60. The first control value CV1c may be greater than the second control value CV2c. The second control value CV2c may be greater than, or equal to, 0. FIG. 15 illustrates an example where the second control value CV2c is greater than 0.

A length of the control period COc may exceed the length of one cycle (e.g., T in FIG. 5 or Ta in FIG. 6) of the output of the source power supply 40. The length of the control period COc may exceed a length of several cycles of the output of the source power supply 40. For example, a length of the control period COc may correspond to a length of time during which the source power supply 40 supplies power for plasma excitation. Additionally, the length of the control period COc may be shorter than a length of time during which the source power supply 40 supplies power for plasma excitation.

The control power supply 70 that applies voltage to each of two plasma control electrodes 60 disposed facing each other may output voltage to the plasma control electrodes 60 according to one of the embodiments described above with reference to FIGS. 10 to 12.

Accordingly, the electric field EF generated from each of the two plasma control electrodes 60 disposed facing each other may be directed toward a space positioned above the support 20. In addition, when the second control value CV2c is 0, the electric field EF generated from the first plasma control electrode 60 (e.g., to which the first control value CV1c is applied) may be directed toward the space positioned above the support 20. Strengths of the electric fields EF generated from each of the two plasma control electrodes 60 disposed facing each other may therefore be different. For example, when a first surface of the first plasma control electrode 60 faces a space positioned above a central region of the support 20, the electric field EF generated by the first plasma control electrode 60 may face a space positioned above the central region of the support 20.

The electric field EF generated by the plasma control electrode 60 may control a state of the plasma positioned in the upper space of the support 20. The electric field EF generated by the plasma control electrode 60 may control a movement state of plasma ions. The ions generated when plasma is excited may have their movement state controlled by the electric field EF. Cations may be influenced in a direction of the electric field. Accordingly, and as illustrated in FIG. 16, the cations may move from a region positioned above an edge region of the support 20 toward a region positioned above the center region of the support 20 due to the electric field EF being oriented toward the center region. Additionally, anions may move in an opposite direction to the cations, for example, with the anions moving from the region positioned above the center region of the support 20 to the region positioned above an edge region of the support 20.

In addition, as described above, a level of power supplied by the source power supply 40 may be pulsed. In this case, the ions generated when the plasma is excited change at a speed slower than a change in the level of power supplied by the source power supply 40. That is, as the level of power supplied by the source power supply unit 40 changes from the high-power level (e.g., H in FIG. 5 or Ha in FIG. 6) to the low power level (e.g., L in FIG. 5 or La in FIG. 6), density of ions generated when plasma is excited begins to decrease relatively gradually from a time when the low-level section (e.g., LS in FIG. 5 or LSa in FIG. 6) begins. For example, as described above in FIG. 5, even when the low power level L of the source power supply 40 is 0 W, density of ions generated when the plasma is excited at the start of the low-level section LS may not become 0. In addition, the control power supply 70 may apply a voltage to the plasma control electrode 60 even when the power level of the source power supply 40 is at a low power level (e.g., L in FIG. 5 or La in FIG. 6). Accordingly, the ions remaining in the space positioned above the support 20 during the low-level section (e.g., LS in FIG. 5 or LSa in FIG. 6) may have their movement direction controlled by the electric field EF generated between the plasma control electrodes 60. For example, when first surfaces of the plasma control electrodes 60 face a space positioned above a central region of the support 20, a state of plasma may be controlled in such a way that density of cations increases toward an upper side of the central region of the support 20 by the electric field EF generated in the plasma control electrode 60.

In addition, density of plasma and density of ions excited by energy applied by the plasma excitation electrode 30 may differ along a horizontal direction relative to a center of the support 20. The horizontal direction may be parallel to an upper surface of the support 20, and, may be in a radial or circumferential direction relative to the support 20 (e.g., when the support 20 comprises a circular shape). For example, the density of plasma excited by energy applied by the plasma excitation electrode 30 may be different at opposite sides in a radial direction based on the center of the support 20. Accordingly, a movement state of ions at opposite sides in the radial direction relative to the center of the support 20 may be varied by varying a magnitude of the voltage applied to the two plasma control electrodes 60 disposed facing each other. As a result, density of the ions at opposite sides in the radial direction may be controlled relative to the center of the support 20. Accordingly, a pair of plasma control electrodes 60 that face each other may generate electric fields EF (e.g., as illustrated in FIG. 16), and the strengths of the electric fields EF may be controlled based on the control value (e.g., CV, CV1, CV2, CV1c, CV2c, etc.) applied to each of the plasma control electrodes 60 by the control power supplies 70. By varying the magnitude of the applied voltage and the strength of the electric fields EF, the pair of plasma control electrodes 60 may control the state of plasma and movement of plasma ions positioned above the support 20.

In a substrate processing apparatus according to an embodiment, a voltage may be applied to the plasma control electrodes 60 as described above in FIGS. 13 and 14 while substrate processing is performed using plasma. In this case, magnitudes of voltages applied to the plasma control electrodes 60 may be the same, or the magnitudes of the voltages applied to at least two plasma control electrodes 60 may be different from the rest.

In addition, in a substrate processing apparatus according to an embodiment, a voltage may be applied to the plasma control electrodes 60 as described above in FIGS. 15 and 16 while substrate processing is performed using plasma. In this case, magnitudes of voltages applied to the plasma control electrodes 60 may be all different, or the magnitudes of the voltages applied to at least two plasma control electrodes 60 may be the same.

In addition, in the substrate processing apparatus 1 according to an embodiment, during substrate processing (e.g., using plasma), a first voltage may be applied to some of the plasma control electrodes 60 as described above in FIGS. 13 and 14, and a second voltage may be applied to the remainder of the plasma control electrodes 60 as described above in FIGS. 15 and 16.

In addition, the substrate processing apparatus 1 according to an embodiment may apply a voltage having a negative value to the plasma control electrode 60 through the control power supply 70 while the substrate is processed using plasma. In this case, among the plasma ions, anions may move in a direction from an edge region above the support 20 toward a central region of the support 20, and cations may move in the opposite direction (e.g., from above the central region of the support 20 toward the edge region). That is, the voltage supplied by the control power supply 70 may be either positive or negative depending on whether an ion contributing to the etching of the substrate is a cation or an anion. Even when the voltage supplied by the control power supply 70 is negative, a control time and a control value may be applied similarly to those described above in FIGS. 10 to 16. That is, the control values described above in FIGS. 10 to 16 may be changed to negative values having same absolute values, so a redundant description thereof will be omitted.

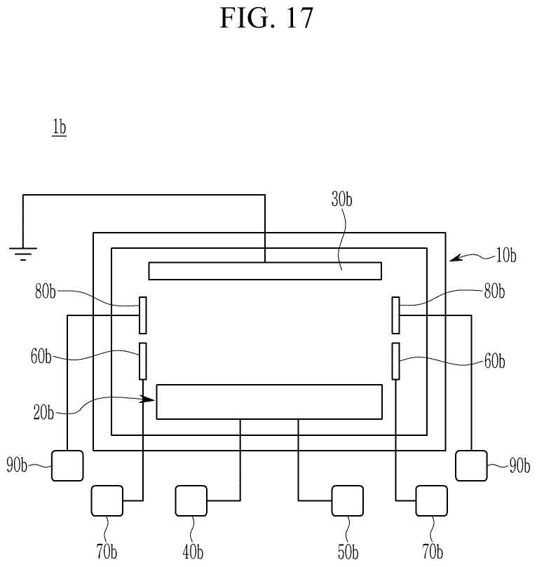

FIG. 17 illustrates a substrate processing apparatus 1b according to another embodiment.

Referring to FIG. 17, the substrate processing device 1b according to another embodiment may include a chamber 10b, a support 20b, a plasma excitation electrode 30b, a source power supply 40b, a bias power supply 50b, a plasma control electrode 60b, a control power supply 70b, an upper plasma control electrode 80b, and an upper control power supply 90b.

The chamber 10b, the support 20b, the plasma excitation electrode 30b, the source power supply 40b, the bias power supply 50b, the plasma control electrode 60b, and the control power supply 70b are the same as or similar to those described above in FIGS. 1 to 16, so redundant descriptions thereof will be omitted.

The upper plasma control electrode 80b may control a state of plasma in a space positioned above the support 20b. For example, the upper plasma control electrode 80b may control distribution of plasma ions positioned above the support 20b. The upper plasma control electrode 80b may have a plate structure having a preset area. The upper plasma control electrode 80b may include at least a portion that is formed of a conductive material.

The upper plasma control electrode 80b may be disposed outside the space positioned above the support 20b. When viewed from above, the upper plasma control electrodes 80b may be disposed adjacent an outer periphery of the support 20b while lying outside of the outer periphery, or footprint, of the support 20b. In some embodiments, the upper plasma control electrodes 80b may be separate from, and spaced apart from, the plasma control electrodes 60b. The upper plasma control electrodes 80b may be positioned above the plasma control electrodes 60b relative to a vertical direction, such that a distance separating the upper plasma control electrodes 80b from the plasma excitation electrode 30b may be less than a distance separating the plasma control electrodes 60b from the plasma excitation electrode 30b. As such, a gap or space may be positioned vertically between the upper plasma control electrodes 80b and the plasma control electrodes 60b. In some embodiments, when viewed from above in a plan view, the upper plasma control electrodes 80b may overlap the plasma control electrodes 60b. The upper plasma control electrodes 80b may be mounted within the chamber 10, for example, by being attached to one or more of the walls of the chamber 10. In some embodiments, the upper plasma control electrodes 80b may be separate from the support 20 and the plasma excitation electrode 30, for example, with the upper plasma control electrodes 80b not in contact with the support 20 and the plasma excitation electrode 30 such that a gap or a space may exist between the upper plasma control electrodes 80b and both the support 20 and the plasma excitation electrode 30.

When viewed from above, the upper plasma control electrode 80b may have a first surface facing the space above the support 20b. That is, a first surface of the upper plasma control electrode 80b may face the space positioned above the support 20b. For example, a line or axis that is perpendicular to the first surface of a first upper plasma control electrodes 80b may be parallel to, and vertically above, a line or axis that is perpendicular to the first surface of a first plasma control electrode 60b, wherein the first upper plasma control electrode 80b overlaps the first plasma control electrode 60b.

When viewed from above, a first surface of the upper plasma control electrode 80b may face a central region of the support 20b. That is, a first surface of the upper plasma control electrode 80b may face the space positioned above the central region of the support 20b. By facing the space above the central region of the support 20b, a line or axis that is perpendicular to the first surface of the upper plasma control electrode 80b may pass through the space above the central region.

The upper plasma control electrode 80b may be disposed above the upper surface of the support 20b while being located outside of the outer periphery of the support 20b. The upper plasma control electrode 80b may be disposed above the plasma control electrode 60b.

A lower end of the upper plasma control electrode 80b may be positioned higher than an upper end of the plasma control electrode 60b. Accordingly, a first surface of the upper plasma control electrode 80b may face a space positioned above the plasma control electrode 60b and the support 20b in the vertical direction.

A plurality of upper plasma control electrodes 80b may be provided, and the plasma control electrodes 80b may be disposed at an outer periphery of the space positioned above the support 20b while being spaced apart from each other. Accordingly, the upper plasma control electrodes 80b may face each other with the space positioned above the support 20b therebetween. For example, two upper plasma control electrodes 80b may be provided facing each other with a space positioned above the center of the support 20b therebetween. As described above relative to the two plasma control electrodes 60 that are arranged to face each other, two upper plasma control electrodes 80b may face each other such that a line or axis that is perpendicular to the first surface of one of the upper plasma control electrodes 80b may be parallel to, and co-linear with, a line or axis that is perpendicular to the first surface of an opposing upper plasma control electrode 80b. In some embodiments, the upper plasma control electrodes 80b may be arranged in an identical manner as the plasma control electrodes 60 illustrated in FIG. 3, wherein an even number of upper plasma control electrodes 80b may be provided, and pairs of the upper plasma control electrodes 80b are arranged to face each other.

A number of the upper plasma control electrodes 80b may be equal to that of the plasma control electrodes 60b. Alternatively, the number of the upper plasma control electrodes 80b may be greater or less than the number of the plasma control electrodes 60b.

The upper control power supply 90b may be electrically connected to the plasma control electrode 80b to provide power for controlling the state of plasma. The upper control power supply 90b may be electrically connected to a region of the upper plasma control electrode 80b that is provided with a conductive material. The upper control power supply 90b may be provided to include a voltage source to output a voltage. The state of the plasma positioned in the space above the support 20b may be controlled by a power supplied by the upper control power supply 90b. A plurality of upper control power supplies 90b may be provided. For example, a number of control power supplies 90b may be equal to that of upper plasma control electrodes 80b. As such, the upper control power supplies 90b may be connected one-to-one to the plasma control electrodes 80b, respectively. For example, one upper control power supply 90b (e.g., a first upper control power supply 90b) may be electrically connected to one upper plasma control electrode 80b (e.g., a first upper plasma control electrode 80b), another upper control power supply 90b (e.g., a second upper control power supply 90b) may be electrically connected to another upper plasma control electrode 80b (e.g., a second upper plasma control electrode 80b), etc. Accordingly, the voltage applied to the upper plasma control electrodes 80b may be individually controlled, for example, with the first upper control power supply 90b applying a first voltage to the first upper plasma control electrode 80b, while the second upper control power supply 90b applies a second voltage to the second upper plasma control electrode 80b, wherein the first voltage may be the same as, or different than, the second voltage. In addition, the number of the upper control power supplies 90b may be smaller than that of the plasma control electrodes 80b. Additionally, at least one of the upper control power supplies 90b may be connected to two or more upper plasma control electrodes 80b. The upper control power supply 90b may supply a voltage in a manner identical or similar to the manner in which the control power supply 70 described above in FIGS. 10 to 16 supplies a voltage, and a redundant description thereof will be omitted.

In accordance with the substrate processing device 1b according to another embodiment, a plasma state of the space above the support 20b may be controlled by the plasma control electrode 60b and the upper plasma control electrode 80b. That is, the plasma state of the space adjacent to the upper surface of the support 20b may be controlled by a voltage applied to the plasma control electrode 60b. In addition, the plasma state of the space positioned above the plasma control electrode 60b may be controlled by a voltage applied to the upper plasma control electrode 80b.

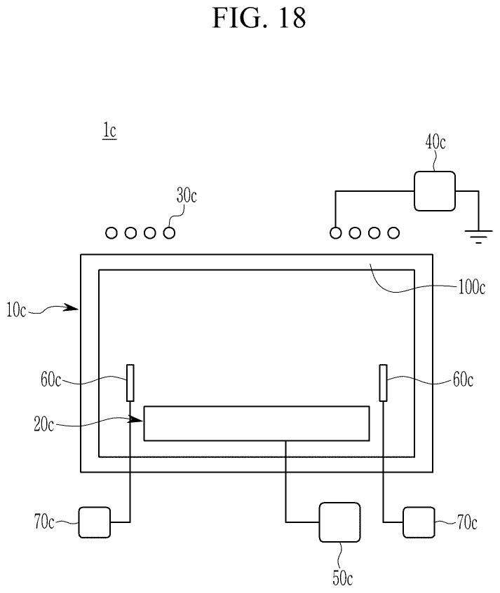

FIG. 18 illustrates a substrate processing apparatus 1c according to another embodiment.

Referring to FIG. 18, the substrate processing device 1c according to another embodiment may include a chamber 10c, a support 20c, a plasma excitation electrode 30c, a source power supply 40c, a bias power supply 50c, a plasma control electrode 60c, and a control power supply 70c.

The support 20c may be identical or similar to that of the support 20 of the substrate processing apparatus 1 described above in FIG. 1, a redundant description thereof will be omitted.

The chamber 10c provides a process space within which a substrate processing process is performed. An upper wall 100c of the chamber 10c may include at least a portion that is formed of a dielectric. Other configurations of the chamber 10c may be identical or similar to the chamber 10 of FIG. 1, so a redundant description will be omitted.

The plasma excitation electrode 30c may apply energy for plasma excitation inside the chamber 10c. The plasma excitation electrode 30c may have an antenna structure. The plasma excitation electrode 30c may be disposed outside the chamber 10c. The plasma excitation electrode 30c may be disposed adjacent to an upper surface of the upper wall 100c of the chamber 10c. The plasma excitation electrode 30c may be disposed to face an inner space of the chamber 10c with an upper wall of the chamber 10c provided therebetween.

The source power supply 40c may provide a power for plasma excitation, and may be similar or identical to the source power supply 40 described herein. The source power supply 40c may be electrically connected to the plasma excitation electrode 30c. The source power supply 40c may include a high-frequency power supply that generates a high-frequency power. The source power supply 40c may include an RF power supply. The plasma excitation electrode 30c may generate electromagnetic waves through power provided by the source power supply 40c. A gas supplied into an interior of the chamber 10c may be excited into plasma by electromagnetic waves generated from the plasma excitation electrode 30c.

The source power supply 40c may output a power for plasma excitation in a manner that is identical to or similar to the embodiments described above with reference to FIGS. 5 and 6, so a redundant description will be omitted.

The bias power supply 50c may be electrically connected to the support 20c to supply a voltage for bias. The bias power supply 50c may be electrically connected to a region provided with a conductive material in the support 20c. A sheath state, a concentration state of plasma on the substrate, a state of incidence of ions on the substrate, etc. may be adjusted in a region adjacent to the upper surface of the support 20c by the voltage supplied by the bias power supply 50c.

The bias power supply 50c may output a voltage that is identical to or similar to the embodiments described above in FIGS. 7 to 9, so a redundant description will be omitted.

Configurations and operating methods of the plasma control electrode 60c and the control power supply 70c may be the same or similar to those described above in FIGS. 1 to 16, so a redundant description will be omitted. In addition, the substrate processing apparatus 1c according to another embodiment may further include an upper plasma control electrode and an upper control power supply that are identical to or similar to those of the substrate processing device 1b described above in FIG. 17, so a redundant description thereof will be omitted.

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

What is claimed is:

1. A substrate processing apparatus comprising:
a chamber;
a plasma excitation electrode configured to apply energy for excitation of plasma within the chamber;
a support disposed inside the chamber and configured to support a substrate;
a plasma control electrode facing a space positioned above the support, wherein the plasma control electrode is separate from, and spaced apart from, the plasma excitation electrode; and
a control power supply connected to the plasma control electrode to supply a power for controlling a state of the plasma.

2. The substrate processing apparatus of claim 1, wherein
the plasma control electrode comprises a plate structure comprising a planar first surface, and wherein an axis that is perpendicular to the first surface extends through the space positioned above the support between the support and the plasma excitation electrode.

3. The substrate processing apparatus of claim 2, wherein
the plasma control electrode is disposed outside of an outer periphery of the support and outside of an outer periphery of the plasma excitation electrode.

4. The substrate processing apparatus of claim 3, wherein
the axis that is perpendicular to the first surface extends through a space positioned above a central region of the support.

5. The substrate processing apparatus of claim 1, wherein
the plasma control electrode is one of a plurality of plasma control electrodes, and the plurality of plasma control electrodes are disposed outside of an outer periphery of the support.

6. The substrate processing apparatus of claim 5, wherein
the control power supply is one of a plurality of control power supplies.

7. The substrate processing apparatus of claim 6, wherein
each plasma control electrode is connected to one control power supply of the plurality of control power supplies.

8. The substrate processing apparatus of claim 1, wherein
the control power supply applies a voltage to the plasma control electrode.

9. The substrate processing apparatus of claim 1, further comprising:
an upper plasma control electrode facing the space positioned above the support, wherein the upper plasma control electrode is disposed above the plasma control electrode; and
an upper control power supply connected to the upper plasma control electrode, and configured to supply a power to the upper plasma control electrode for controlling the state of the plasma.

10. The substrate processing apparatus of claim 9, wherein
the upper plasma control electrode has a plate structure comprising a planar first surface, and wherein an axis that is perpendicular to the first surface of the upper plasma control electrode extends through the space positioned above the support between the support and the plasma excitation electrode.

11. The substrate processing apparatus of claim 10, wherein
the upper plasma control electrode is disposed outside of an outer periphery of the support and outside of an outer periphery of the plasma excitation electrode.

12. The substrate processing apparatus of claim 9, wherein
the upper plasma control electrode is one of a plurality of upper plasma control electrodes, and the plurality of upper plasma control electrodes are disposed outside of an outer periphery of the support.

13. The substrate processing apparatus of claim 9, wherein
the upper control power supply applies a voltage to the upper plasma control electrode.

14. A substrate processing apparatus comprising:
a chamber;
a plasma excitation electrode configured to apply energy for excitation of plasma within the chamber;
a support disposed inside the chamber and configured to support a substrate;
a source power supply configured to supply a power for plasma excitation in a form of pulsing a power level;
a plasma control electrode facing a space positioned above the support, wherein the plasma control electrode is separate from, and spaced apart from, the plasma excitation electrode; and
a control power supply connected to the plasma control electrode to apply a voltage for controlling a state of the plasma.

15. The substrate processing apparatus of claim 14, wherein
a lower surface of the plasma excitation electrode is positioned inside the chamber facing the support in a vertical direction.

16. The substrate processing apparatus of claim 14, wherein
the plasma excitation electrode has an antenna structure, and is outside the chamber.

17. The substrate processing apparatus of claim 14, wherein
the plasma control electrode is one of a plurality of plasma control electrodes, and a voltage applied to each of the plasma control electrodes is individually controlled.

18. A substrate processing apparatus comprising:
a chamber;
a plasma excitation electrode configured to apply energy for excitation of plasma within the chamber;
a support disposed inside the chamber and configured to support a substrate;
a source power supply configured to supply a power for plasma excitation in a form of pulsing a power level;
a bias power supply electrically connected to the support and configured to supply a power for bias;
a plasma control electrode facing a space positioned above the support, wherein the plasma control electrode is separate from, and spaced apart from, the plasma excitation electrode; and
a control power supply connected to the plasma control electrode to apply a voltage for controlling a state of the plasma.

19. The substrate processing apparatus of claim 18, wherein
the control power supply supplies a voltage of a control value to the plasma control electrode during a control period.

20. The substrate processing apparatus of claim 19, wherein
a length of the control period exceeds a length of one cycle of an output of the source power supply.

21. A substrate processing apparatus comprising:
a chamber;
a plasma excitation electrode configured to apply energy for excitation of plasma within the chamber;
a support disposed inside the chamber and configured to support a substrate;
a first plasma control electrode facing a space positioned above the support;
a second plasma control electrode facing the space positioned above the support, wherein an axis that is perpendicular to a first surface of the second plasma control electrode extends through the space positioned above the support between the support and the plasma excitation electrode and passes through a first surface of the first plasma control electrode;
a first control power supply connected to the first plasma control electrode to apply a voltage to the first plasma control electrode; and
a second control power supply connected to the second plasma control electrode to apply a voltage to the second plasma control electrode.

22. The substrate processing apparatus of claim 21, further comprising:
a first upper plasma control electrode facing the space positioned above the support, the first upper plasma control electrode overlapping the first plasma control electrode; and
a second upper plasma control electrode facing the space positioned above the support, the second upper plasma control electrode overlapping the second plasma control electrode, wherein a second axis that is perpendicular to a first surface of the second upper plasma control electrode extends through the space positioned above the support between the support and the plasma excitation electrode and passes through a first surface of the first upper plasma control electrode.

23. The substrate processing apparatus of claim 22, further comprising:
a first upper control power supply connected to the first upper plasma control electrode to apply a voltage to the first upper control power supply; and
a second upper control power supply connected to the second upper plasma control electrode to apply a voltage to the second upper control power supply.

24. The substrate processing apparatus of claim 23, further comprising:
a source power supply electrically connected to the support and configured to supply a power to the support for plasma excitation in a form of pulsing a power level; and
a bias power supply electrically connected to the support and configured to supply a power for bias.
